(19) United States
(12) Patent Application Publication
(10) Pub. No.: US 2025/0115482 A1
(43) Pub. Date: Apr. 10, 2025

(54) MANUFACTURING OF MULTIFUNCTIONAL NANOSTRUCTURES USING SUPERCRITICAL CO2-ASSISTED SPRAY DEPOSITION

(71) Applicant: The Texas A&M University System, College Station, TX (US)

(72) Inventors: Dorrin Jarrahabshi, College Station, TX (US); Amir Asadi, College Station, TX (US); Shadi Shariatinia, College Station, TX (US)

(73) Assignee: The Texas A&M University System, College Station, TX (US)

(21) Appl. No.: 18/832,329

(22) PCT Filed: Jan. 20, 2023
(86) PCT No.: PCT/US2023/011282

§ 371 Date: Jul. 23, 2024

Related U.S. Application Data
(60) Provisional application No. 63/302,491, filed on Jan. 24, 2022.

(51) Int. Cl. C01B 32/156; B05D 1/02; B82Y 30/00; C01B 32/168

(52) U.S. Cl. CPC C01B 32/156; B05D 1/025; B82Y 30/00; C01B 32/168

(57) ABSTRACT

In an embodiment, the present disclosure pertains to a method of deposition of nanostructures with engineered patterns. In an additional embodiment, the present disclosure pertains to a method of preparing colloidal suspensions of hybrid nanoparticle systems (HNMS). In a further embodiment, the present disclosure pertains to a method of making a cellulose nanocrystal (CNC)-bonded carbon nanotube carbon fiber reinforced polymer (CNT-CFRP) hybrid composite. In another embodiment, the present disclosure pertains to a method of making a cellulose nanocrystal (CNC)-bonded graphene nanoplatelets (GNP) carbon fiber reinforced polymer (GNP-CFRP) hybrid composite. In a further embodiment, the present disclosure pertains to a method of making a hybrid cellulose nanocrystal (CNC)-graphene nanoplatelet(boron nitride nanobarb) (GNP-(BNNB))-carbon fiber (CF)Zpolyether ether ketone (PEEK) using spray-coating.

### CROSS-REFERENCE TO RELATED APPLICATIONS

This patent application claims priority from, and incorporates by reference the entire disclosure of, U.S. Provisional Patent Application 63/302,491 filed on Jan. 24, 2022.

### STATEMENT REGARDING FEDERALLY SPONSORED RESEARCH

This invention was made with government support under 1930277 and 2134456 awarded by National Science Foundation. The government has certain rights in the invention.

### TECHNICAL FIELD

The present disclosure relates generally to manufacturing of two- and three-dimensional multifunctional nanostructures and more particularly, but not by way of limitation, to manufacturing of two- and three-dimensional multifunctional nanostructures using super critical CO₂-assisted spray deposition and evaporation of colloidal droplets.

### BACKGROUND

This section provides background information to facilitate a better understanding of the various aspects of the disclosure. It should be understood that the statements in this section of this document are to be read in this light, and not as admissions of prior art.

Integrating nanomaterials (NMs) within various manufacturing techniques has enabled producing parts with emerging functionalities. A lack of control in NMs pattern that forms the microstructure leads to poor manufacturing reproducibility and low performance. To date, there is no high-throughput spray-based processing technique that allows precise controlling of the microstructures for large-scale applications. The methods disclosed herein overcome the existing challenges by combining a novel and scalable spray deposition process capable of controlling droplet properties and innovative building units (hybrid nanomaterials system; HNMS) to deposit desired patterns. Tailored nanostructures are composed from these patterns without the need for costly treatments.

### SUMMARY OF THE INVENTION

This summary is provided to introduce a selection of concepts that are further described below in the Detailed Description. This summary is not intended to identify key or essential features of the claimed subject matter, nor is it to be used as an aid in limiting the scope of the claimed subject matter.

In an embodiment, the present disclosure pertains to a method of deposition of nanostructures with engineered patterns. In general, the method includes selecting nanoparticles and a substrate, and delivering the nanoparticles to the substrate via a supercritical CO₂-assisted atomization (SAA) system.

In an additional embodiment, the present disclosure pertains to a method of preparing colloidal suspensions of hybrid nanomaterials systems (HNMS). HNMS are hybrid materials system with designed amphiphilicity (hydrophilicity vs. hydrophobicity). In general, the method includes dispersing nanomaterials (e.g. nanoparticles) having different shapes, sizes, and elemental compositions in water and sonicating the water with a sonication probe to prepare the HNMS.

In a further embodiment, the present disclosure pertains to a method of making a cellulose nanocrystal (CNC)-bonded carbon nanotube carbon fiber reinforced polymer (CNT-CFRP) hybrid composite. In general, the method includes: (1) dispersing carbon nanotubes (CNTs) in deionized water with CNCs to form a mixture; (2) sonicating the mixture; (3) immersing a carbon fiber (CF) fabric with the sonicated mixture in a bath sonicator to enhance deposition of the CNC-CNT on the CF fabric; and (4) manufacturing a CNC-CNT-CF/epoxy hybrid composite using vacuum assisted resin transfer molding (VaRTM).

In another embodiment, the present disclosure pertains to a method of making a cellulose nanocrystal (CNC)-bonded carbon nanotube carbon fiber reinforced polymer (CNT-CFRP) hybrid composite. In general, the method includes: (1) dispersing pristine carbon nanotubes (pCNTs) in deionized water with CNCs to form a mixture; (2) sonicating the mixture; (3) immersing a carbon fiber (CF) fabric with the sonicated mixture in a bath sonicator to enhance deposition of the CNC-pCNT on the CF fabric; and (4) manufacturing a CNC-CNT-CF/epoxy hybrid composite using vacuum assisted resin transfer molding (VaRTM).

In an additional embodiment, the present disclosure pertains to a method of making a cellulose nanocrystal (CNC)-bonded carbon nanotube carbon fiber reinforced polymer (CNT-CFRP) hybrid composite. In general, the method includes: (1) dispersing functionalized CNTs (fCNTs) in deionized water with CNCs to form a mixture; (2) sonicating the mixture; (3) immersing a carbon fiber (CF) fabric with the sonicated mixture in a bath sonicator to enhance deposition of the CNC-fCNT on the CF fabric; and (4) manufacturing a CNC-CNT-CF/epoxy hybrid composite using vacuum assisted resin transfer molding (VaRTM).

In a further embodiment, the present disclosure pertains to a method of making a hybrid cellulose nanocrystal (CNC)-graphene nanoplatelet (boron nitride nanobarb) (GNP-(BNNB))-carbon fiber (CF)/polyether ether ketone (PEEK) using spray-coating. In general, the method includes: (1) dispersing BNNBs, CNCs, and GNPs in deionized water to form a mixture; (2) treating a CF/PEEK prepreg with a plasma surface treatment; (3) coating the CF/PEEK prepreg with the mixture via a supercritical CO₂-assisted atomization (SAA) system; and (4) forming the hybrid CNC-GNP(BNNB)-CF/PEEK via compression molding of the CF/PEEK prepreg.

In a further embodiment, the present disclosure pertains to a method of making a cellulose nanocrystal (CNC)-bonded carbon nanotube/graphene nanoplatelets carbon fiber reinforced polymer (CNT/GNP-CFRP) hybrid composite. In general, the method includes: (1) dispersing carbon nanotubes (CNTs) and graphene nanoplatelets (GNPs) in deionized water with CNCs to form a mixture; (2) sonicating the mixture; (3) immersing a carbon fiber (CF) fabric with the sonicated mixture in a bath sonicator to enhance deposition of the CNC-CNT on the CF fabric; and (4) manufacturing a CNC-CNT/GNP-CF/epoxy hybrid composite using vacuum assisted resin transfer molding (VaRTM).

In another embodiment, the present disclosure pertains to a method of making a cellulose nanocrystal (CNC)-bonded carbon nanotube/graphene nanoplatelet carbon fiber reinforced polymer (CNT-CFRP) hybrid composite. In general, the method includes: (1) dispersing pristine carbon nanotubes (pCNTs) and pristine graphene nanoplatelets (GNPs) in deionized water with CNCs to form a mixture; (2) sonicating the mixture; (3) immersing a carbon fiber (CF) fabric with the sonicated mixture in a bath sonicator to enhance deposition of the CNC-pCNT on the CF fabric; and (4) manufacturing a CNC-CNT/GNP-CF/epoxy hybrid composite using vacuum assisted resin transfer molding (VaRTM).

In a further embodiment, the present disclosure pertains to a cellulose nanocrystal (CNC)-bonded carbon nanotube carbon fiber reinforced polymer (CNT-CFRP) hybrid composite composition formed via the methods as disclosed herein.

In an additional embodiment, the present disclosure pertains to a cellulose nanocrystal (CNC)-bonded carbon nanotube carbon fiber reinforced polymer (CNT-CFRP) hybrid composite composition formed via the methods as disclosed herein.

In another embodiment, the present disclosure pertains to a cellulose nanocrystal (CNC)-bonded carbon nanotube carbon fiber reinforced polymer (CNT-CFRP) hybrid composite composition formed via the methods as disclosed herein.

In an additional embodiment, the present disclosure pertains to a hybrid cellulose nanocrystal (CNC)-graphene nanoplatelet(boron nitride nanobarb) (GNP-(BNNB))-carbon fiber (CF)/polyether ether ketone (PEEK) composition formed via the methods as disclosed herein.

In a further embodiment, the present disclosure pertains to a cellulose nanocrystal (CNC)-bonded carbon nanotube/graphene nanoplatelets carbon fiber reinforced polymer (CNT/GNP-CFRP) hybrid composite composition formed via the methods as disclosed herein.

In an additional embodiment, the present disclosure pertains to a cellulose nanocrystal (CNC)-bonded carbon nanotube/graphene nanoplatelet carbon fiber reinforced polymer (CNT-CFRP) hybrid composite composition formed via the methods as disclosed herein.

### BRIEF DESCRIPTION OF THE DRAWINGS

A more complete understanding of the subject matter of the present disclosure may be obtained by reference to the following Detailed Description when taken in conjunction with the accompanying Drawings wherein:

FIG. 1 illustrates zeta potential in water (n:m indicates the mass ratio of constituting NMs).

FIG. 2 illustrates the water contact angle (WCA) of pure water droplets on films made with hybrid nanomaterials system (HNMS).

FIG. 3 illustrates an in-house supercritical CO₂-assisted atomization (SAA) system and optical diagnostic setup.

FIG. 4 illustrates Sauter mean diameter (SMD) of aqueous CNC droplets produced via SAA at 20 cm from the nozzle.

FIG. 5 illustrates pattern vs. concentration SAA produced patterns and height profile across droplet for 0.2, 0.5, 2 wt % aqueous CNC in 3 μm droplet.

FIG. 6 illustrates pattern vs. droplet diameter SAA produced height profile across droplet for 2 wt % aqueous CNC and 3-11 μm droplet diameter.

FIG. 7 illustrates sheet electrical resistivity.

FIG. 8A illustrates bonding energy between the existing pairs for GNP-CNC.

FIG. 8B illustrates mean squared displacement (MSD) for (FIG. 8B1) GNP-CNC 12:1 and (FIG. 8B2) GNP-CNC 1:4.

FIG. 9 illustrates comparison of AFM intermolecular forces and molecular dynamics (MD) total bonding energies of GNP-CNC.

FIGS. 10A-10C illustrate mean square displacement of (FIGS. 10A1, FIGS. 10A2) CNC-GNP, (FIGS. 10B1, FIGS. 10B2) CNC-CNT, and (FIGS. 10C1, FIGS. 10C2) CNC-BNNT pairs.

### DETAILED DESCRIPTION

It is to be understood that the following disclosure provides many different embodiments, or examples, for implementing different features of various embodiments. Specific examples of components and arrangements are described below to simplify the disclosure. These are, of course, merely examples and are not intended to be limiting. The section headings used herein are for organizational purposes and are not to be construed as limiting the subject matter described.

A novel spray deposition manufacturing method is described herein, in which supercritical CO₂-assisted atomization (SAA) is employed to manufacture three-dimensional (3D) multi-material nanostructures by depositing hybrid nanomaterials system (HNMS) embedded in controlled size droplets. Irrespective of the shape and type of nanomaterials (NMs), the amphiphilicity degree of HNMS and the ratio of the droplet's diameter-to-HNMS' total mass inside droplets determine the balance of attractive, repulsive and directional intermolecular forces between HNMS, solvent and substrate, which in turn dictate the shape, size and height of the created NMs patterns. The following is elucidated herein: (1) the role of HNMS amphiphilicity on molecular interactions between HNMS, solvent and substrate and the resultant intermolecular force balance; and (2) the effect of droplet size and HNMS mass in droplet on the intermolecular force balance that dictate the NMs patterns in the spray-deposition process. Three systems are used: (i) NMs of different types and geometries to construct HNMS; (ii) HNMS in different solvents and substrates; and (iii) SAA-produced aqueous droplets containing HNMS with various diameter and mass concentrations. To achieve the objectives, HNMS amphiphilicity is characterized, and the evolution of intermolecular forces between HNMS, solvent and substrate during droplet evaporation is studied, and the effect of amphiphilicity and sprayed droplets' properties on these forces using spectroscopy, laser diffraction, and in-situ atomic force microscopy (AFM) is elucidated. Cellulose nanocrystals (CNCs) are used as a platform to engineer the amphiphilicity degree of the HNMS. CNCs are useful to disperse and stabilize pristine carbonaceous nanoparticles such as carbon nanotubes (pCNTs), graphene nanoplatelets (pGNP), fullerene, ceramic nanoparticles such as boron nitride nanotubes, nanobarbs and nnaosheets, in protic media without functionalization. Here, the underlying mechanisms at the molecular level between CNC and pCNT/pGNP that stabilize their dispersion in polar solvents is demystified. Based on the characterization of CNC-pCNT/pGNP using spectroscopy and microscopy along with density functional theory (DFT) simulations, proposed herein is that the main intermolecular mechanism between CNC and pCNT/pGNP is the formation of carbon-oxygen covalent bonds between hydroxyl groups on CNCs and defects on pCNTs/pGNPs leading to stabilization in polar solvents. These findings indicate that the CNC-assisted process enables new capabilities in harnessing new structures at the molecular level and tailoring the performance of nanocomposites at higher length scales.

Carbonaceous nanoparticles such as carbon nanotubes (CNTs) and GNPs have been widely exploited as fillers or as a coating on reinforcing fibers in polymer matrix composites (PMCs) to improve structural and electrical/thermal properties. Despite the attempts to incorporate CNTs/GNPs in polymers and PMCs such as melt/solution-mixing, and in-situ polymerization, their mixtures often involves CNTs/GNP agglomeration, poor interfacial interactions, and deterioration of intrinsic CNT/GNP properties. Although functionalization is effective to disperse CNT/GNP, this method involves harsh chemical processes that impair CNTs/GNPs properties and limits process efficiency. Previous studies show that assisted-nanoparticles enable aqueous-dispersion of exfoliated zirconium phosphate nanoplatelets, zirconium oxide, CNT/GNP combined with hydroxyl (—OH) group abundant nanomaterials such as graphene oxide (GO), and with metallic particles attached to the side walls. Cellulose nanocrystals (CNCs) enable stabilization of pGNP and pCNT in polar media without the need for functionalization. The uniqueness of CNCs is their ability to synergistically enhance the multi-material system functionality such as optical/thermal management in electronic components and structural performance of various systems. Recent studies articulated a novel technique to incorporate CNC assisted pCNT into carbon fiber reinforced polymers (CFRP) and their effect on mechanical properties. It was shown that not only do CNCs disperse and stabilize pCNTs in water, it also increases the flexural and interlaminar shear strength of CFRPs due to the synergistic effect of pCNTs with CNCs.

In an embodiment of the claimed invention, the molecular interactions between CNC and pCNT/pGNP that leads to unbundling and stabilizing in water are revealed. Both experimental and quantum-level DFT simulations indicate that non-bonding (physical) interactions between CNC and pCNT/pGNP cannot be the only mechanism to disperse carbonaceous nanomaterials in water. Irreversible covalent bonds formed between CNC and defected sites on pCNT/pGNP are the main mechanisms that result in debundling and stabilizing the carbonaceous nanoparticles in polar solvents.

A novel supercritical CO₂-assisted spray process to manufacture three-dimensional multi-material nanostructured layouts is described herein by composing NMs patterns that are created through deposition of innovative building units i.e., HNMS, embedded in controlled size aqueous droplets. The HNMS is a multi-material system that is composed of different shapes/sizes/types of NMs and opposite amphiphilic (hydrophilic vs. hydrophobic) properties bonded together with a specified mass fraction. The results show that: (1) in supercritical CO₂-assisted atomization (spray), CO₂ dissolution in water at temperatures and pressures above the thermodynamic critical point of CO₂ enables controlling the droplet sizes that carry HNMS; and (2) the shape and height of the spray-deposited patterns created by HNMS aqueous droplets depend on the mass fraction of NMs that constitute HNMS, concentration of HNMS, and the droplet size.

CNTs (length l: 1.5 μm and diameter d: 10 nm), GNPs (1, width w: 2-5 μm, 6 nm thick), and BNNTs (Boron Nitride nanotubes) (l: 2 jam, d: 80 nm) were separately dispersed in CNC (d: 2.3-4.5 nm, 1: 44-108 nm)+DI-water with various ratios at concentrations of 0.05-0.2 wt % and probe-sonicated for 2 h at 20 kHz and 75% amplitude. To study the HNMS in individual droplets and formed NMs patterns, for each HNMS, six droplets with diameter of ˜1.6 mm were deposited on glass substrate (micro cover glass No. 1.5) using a 0.1 μL Eppendorf pipette. Droplet evaporation time was ˜16 min at 23° C.±0.1 and 50% humidity.

To study the hydrophobicity of HNMS, water contact angle was measured using a Goniometer by depositing a pure water droplet on HNMS film. HNMS films were prepared by depositing 1 mL of the prepared HNMS suspensions on Teflon film taped inside a Petri dish and dried at 80° C. for 4 h.

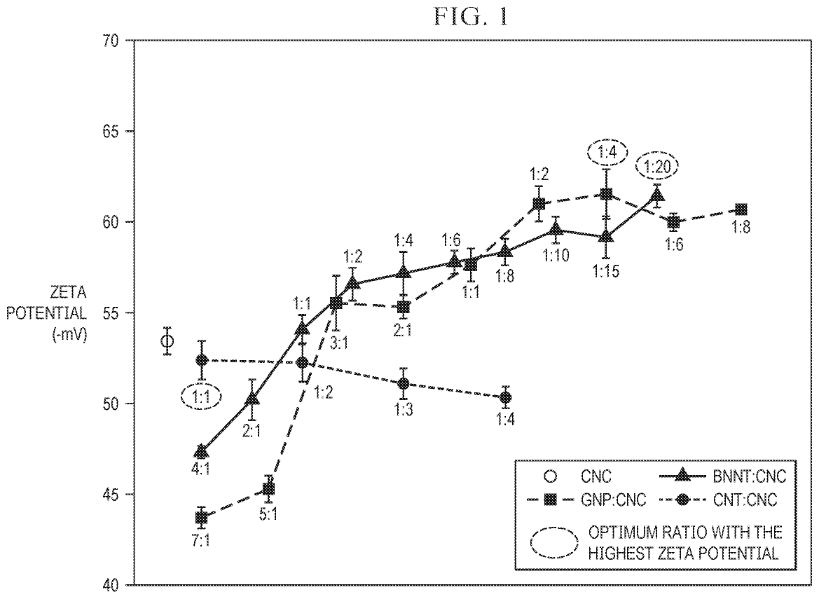

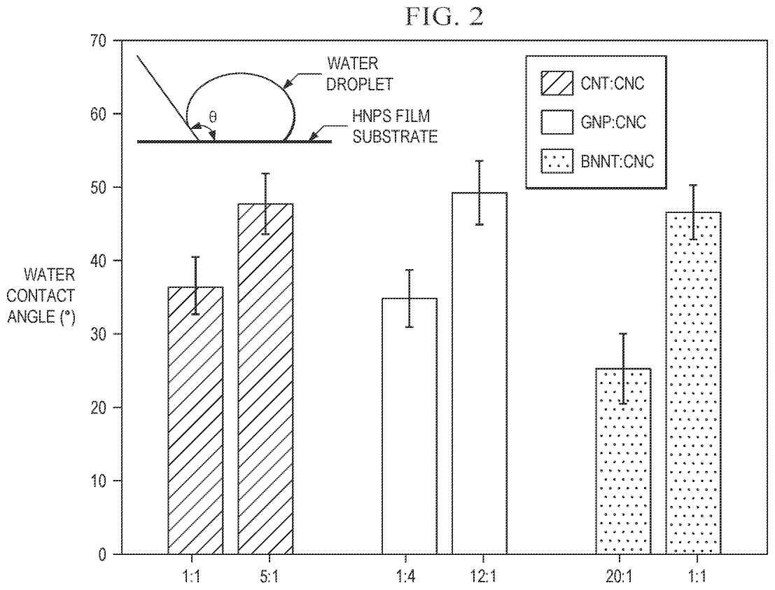

The effect of mass fraction of constituting NMs on the amphiphilicity of HNMS was studied. CNC is efficient in dispersing and stabilizing hydrophobic pristine CNTs, GNPs, and BNNTs in water without the need for functionalization or using a dispersant. In the absence of CNC, hydrophobic CNT, GNP and BNNT settle in a few minutes after stopping the sonication. FIG. 1 shows the zeta-potential (Malvern Zetasizer) of HNMS in water. A higher-zeta potential value indicates higher hydrophilicity of HNMS and better dispersion in water. FIG. 1 indicates that the change in the mass ratio (fraction) of constituting NMs changes HNMS amphiphilicity: increasing CNC ratio increases HNMS hydrophilicity as CNCs possess abundant hydroxyl groups and negatively charged sulfate half-ester groups. When hydrophobicity of HNMS increases, they will not be stable in water and Z-potential test cannot be performed, as such water contact angle (WCA, ASTM D7334) was used to test and understand the relationship between NMs mass fraction and HNMS hydrophobicity by depositing a pure water droplet on a HNMS. Increasing the mass ratios of CNT, GNP, or BNNT to CNCs in the HNMS, increases WCA, indicating that HNMS hydrophobicity increases (FIG. 2). These results imply that regardless of NM's shape, size and type, changing mass fraction of constituting NMs changes HNMS amphiphilicity.

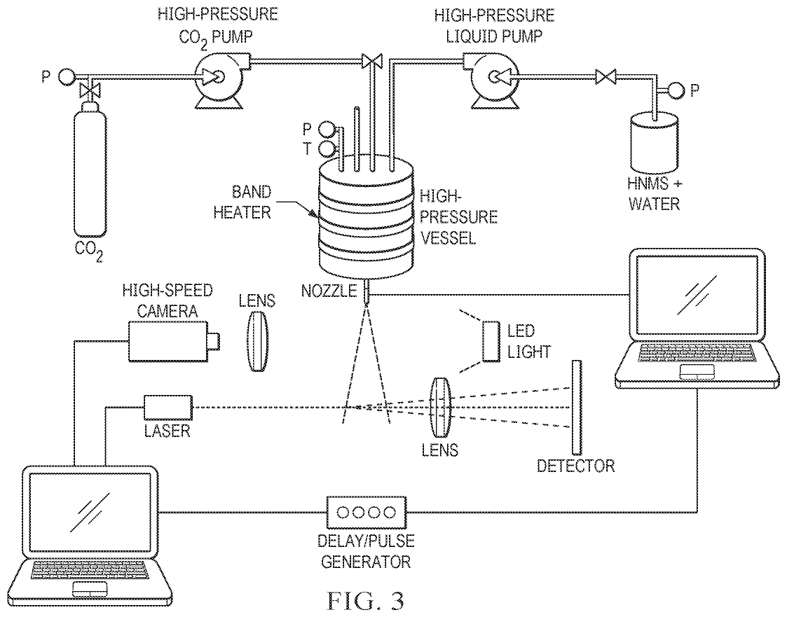

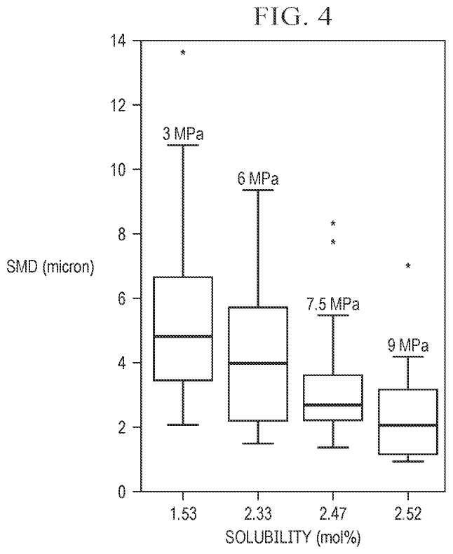

FIG. 3 presents a schematic of the experimental setup having two high-pressure pumps for liquid and gas, a custom-designed high-pressure vessel, 125 μm custom-made single-hole nozzle and an optical diagnostic system. The effect of injection pressure has been fully characterized, temperature, and the CO₂ concentration in the mixture on droplets size. The HNMS suspension is pumped into the high-pressure vessel where it mixes with a high-pressure CO₂. The pressurized ternary mixture (water-HNMS-CO₂) is atomized to micron-sized droplets containing HNMS and deposited on a substrate at 25° C.±0.1 and 50% humidity. A laser diffraction system (Malvern Panalytical's) captured droplets diameter at different axial locations downstream of the nozzle. FIG. 4 shows the box-plot distribution of Sauter mean diameter (SMD; diameter of droplets with the same ratio of volume to surface area) for aqueous CNC (0.2 wt %) generated by SAA. FIG. 4 reveals that the increase of CO₂ pressure increases CO₂ solubility in water and decreases droplet size and narrows its distribution. At and beyond supercritical pressures (7.5 and 9 MPa), SMD has the smallest size and variance. These results show that the built SAA system can produce HNMS containing droplets with controlled size at resolution of 2±0.7 μm.

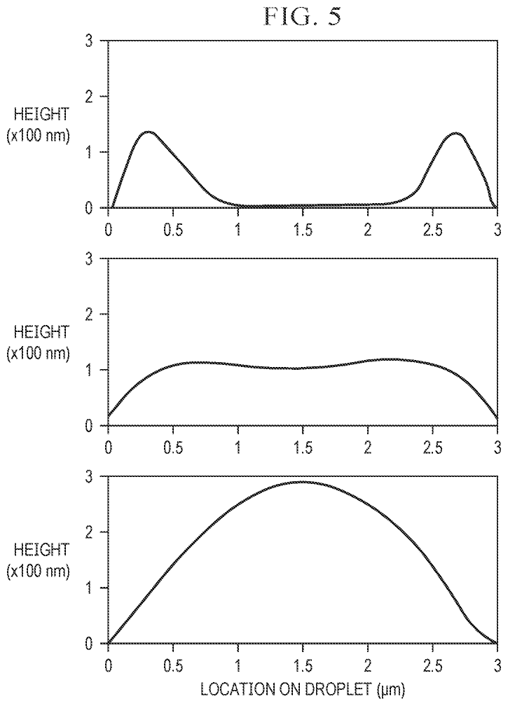

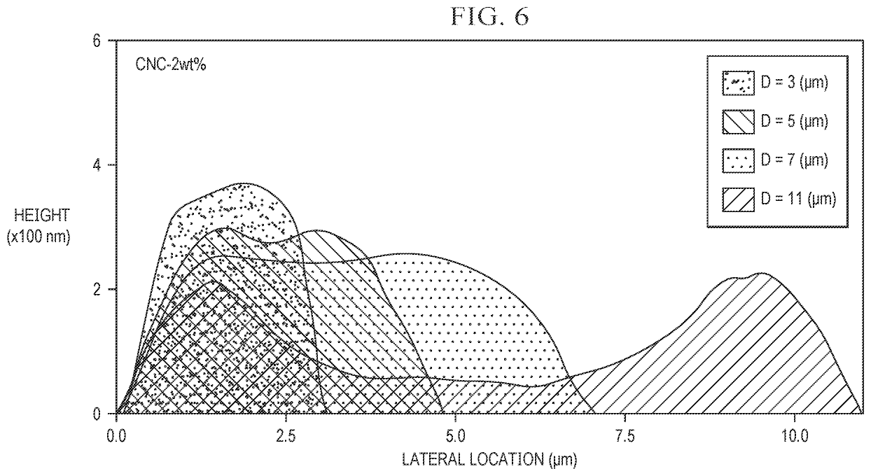

FIG. 5 shows the height profiles of evaporated aqueous CNC droplets with a constant diameter of 3 μm and varied concentrations of 0.2, 0.5 and 2 wt % created by the SAA system at 7.5 MPa on a glass substrate. FIG. 5 indicates that at a constant droplet diameter, by increasing the CNC concentration, the CNC pattern changes from ring to disk and dome, which is against previous studies that report rod-shaped particles, similar to CNC, tend to accumulate at the liquid-air interface. FIG. 6 compares the height profiles for a constant CNC concentration (2 wt %) and varied droplets diameter and highlights that patterns transition from dome to ring by increasing the droplet size. It is noted that Peclet (Pe) number commonly used to describe the assembly of NMs in liquid droplets by interrelating NMs' Brownian diffusion and evaporation-induced flow (advective), cannot describe these patterns. For instance, Pe for 0.2 and 0.5 wt % CNC in a 3 μm-droplet is almost similar (0.33, 0.34), however, the patterns are different (ring vs. disk, FIG. 5). Formation of different patterns of the same NM for (i) different NM concentrations with a constant droplet diameter and (ii) different droplet diameters with a constant concentration (FIG. 5-FIG. 6) imply that in addition to amphiphilicity, the ratio of droplet size to HNMS mass concentration is another key factor in NMs patterning. This is addressed in Hypothesis 2.

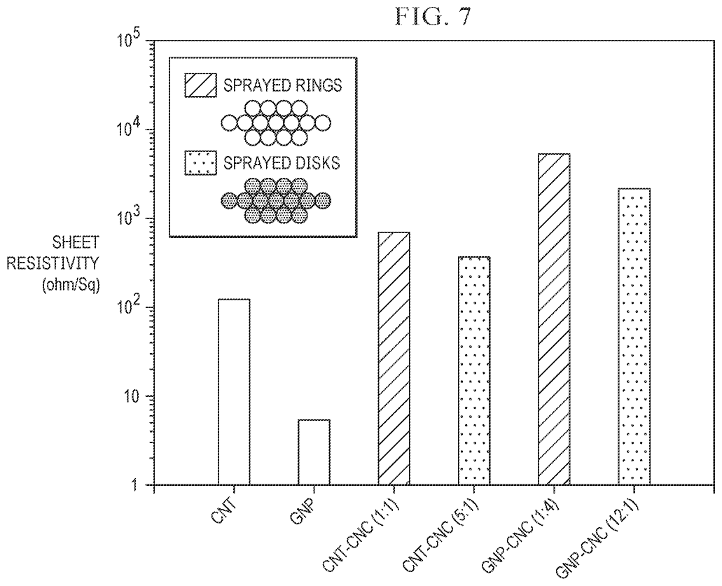

Droplets of 3-5 μm containing GNP-CNC and CNT-CNC were spray-deposited at 7.5 MPa to cover 1 cm² of glass substrate. The NMs ratios and HNMS concentration were selected based on the results from HNMS patterns created after water evaporation vs. HNMS amphiphilicity for GNP CNC, CNT CNC and BNNT CNC and data from FIG. 5 to cover the substrate with either all rings or all disks after droplets evaporation. The sheet electrical resistivity of the nanostructures was measured by four-point probe (Veeco FPP 500, NY, US) shown in FIG. 7. Pure pristine CNT and GNP were fabricated as a film for comparison. Higher resistivity (lower conductivity) is recorded for GNP-CNC (1:4) and CNT-CNC (1:1) that form ring in which conductive GNP and CNT only exist in the periphery. By shifting to disk, i.e. GNP-CNC (12:1) and CNT-CNC (5:1), the resistivity decreases as conductive NPs cover the whole surface area. These results highlight that the proposed spray-deposition enables fabricating multi-material nanostructures with desired functionality.

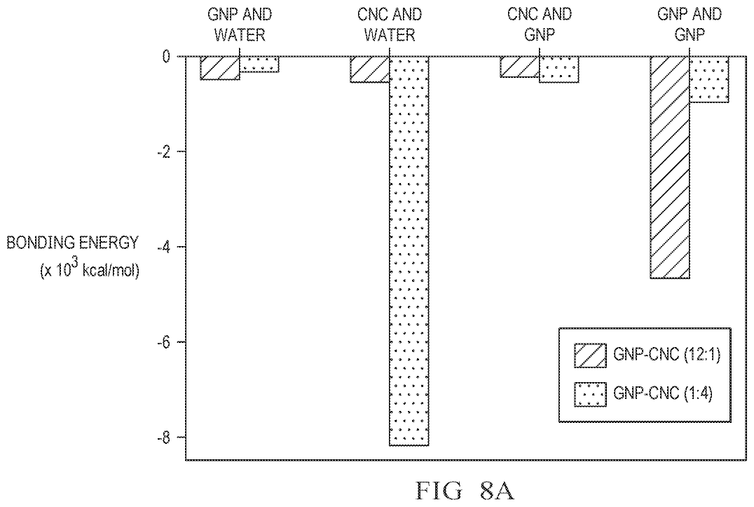

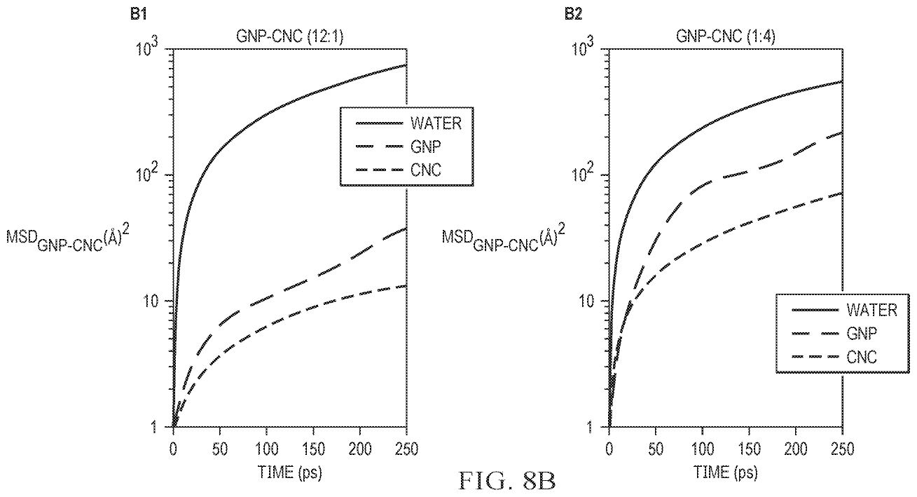

FIG. 8A resolves the intermolecular forces of CNC & water, CNC & GNP, GNP & GNP and GNP & water in a GNP-CNC system with different ratios (12:1, 1:4) in a water droplet. CNC & CNC bonding energy in water is negligible as CNCs are well dispersed and the interaction is long-range electrostatic repulsion (high zeta potential; FIG. 1). A more negative value indicates a stronger bond. Comparing the GNP:CNC (12:1) with (1:4) shows that: (i) increasing CNC ratio increases the bonding energy of CNC & water and increasing GNP ratio increases GNP and GNPs; and (ii) interactions between CNC & GNP are very low. The main molecular interactions in CNC & water are hydrogen bonds (directional), in GNP & GNP is van der Waals (attractive), and in CNC & GNP is π-bonds (weak attractive). CNC & GNP weak bonding energy suggests that interaction of GNP and CNC from neighboring HNMS is minimal. Correlating MD results with the patterns in HNMS patterns created after water evaporation vs. HNMS amphiphilicity for GNP CNC, CNT CNC and BNNT CNC exhibits that the main intermolecular forces in patterning are van der Waals (attractive), electrostatic repulsion (repulsive) and hydrogen bonds (directional). FIG. 8B shows mean squared displacement (MSD) for (FIG. 8B1) GNP-CNC 12:1 and (FIG. 8B2) GNP-CNC 1:4

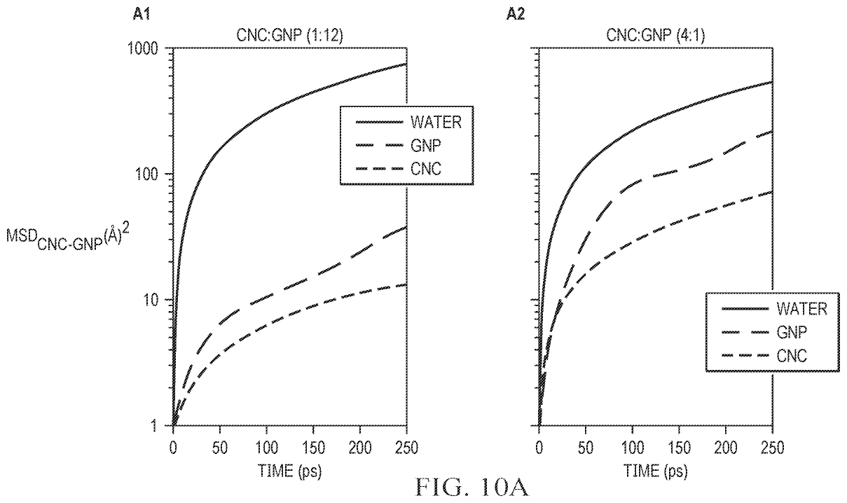

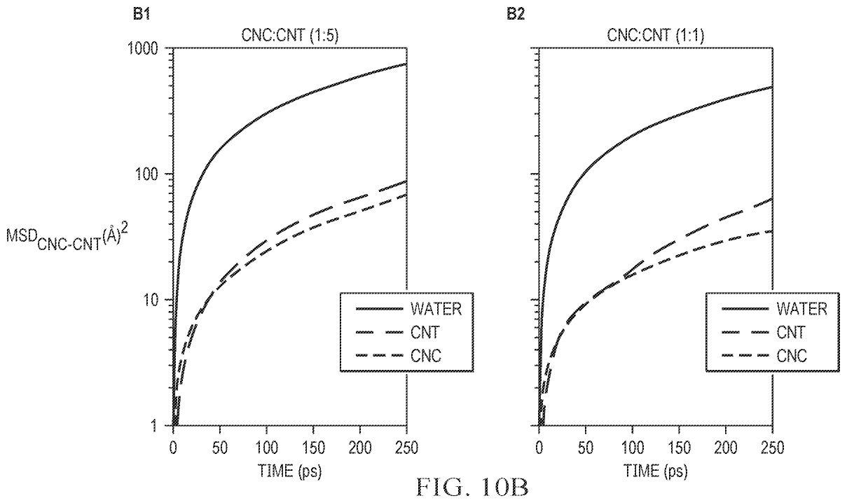

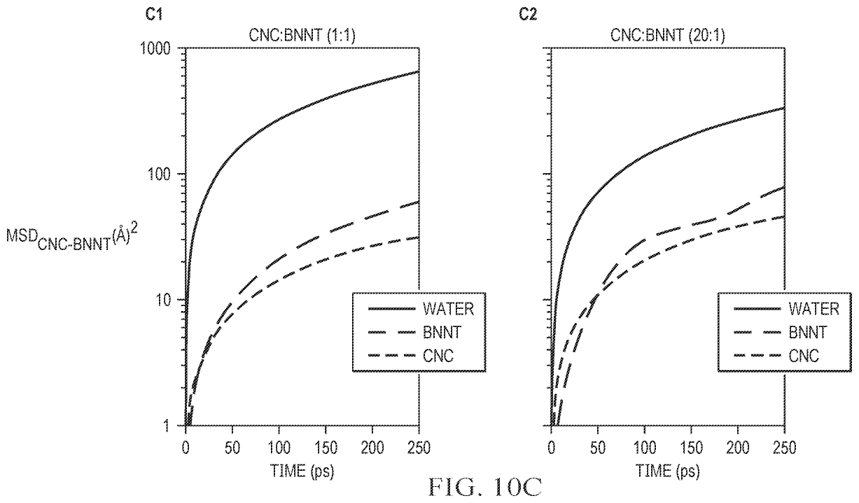

FIG. 10B compares the movement of GNP, CNC and water molecules over time by measuring the mean squared displacement values (MSD) for GNP:CNC of 12:1 and 1:4. MSD is cumulative displacement of a particle over time. Comparing bonding energy between the existing pairs for GNP-CNC and MSD show that when GNP content is higher and CNC is lower (12:1 compared to 1:4), the MSD of GNP is lower possibly due GNPs aggregation and MSD of water molecules higher, as they have more freedom to move. In contrast, when GNP content decreases and CNC's increases (4:1 compared to 12:1), more water molecules interact with CNCs and the overall MSD of the water molecules reduces. Interestingly, MSD values for GNP increases possibly because GNP aggregation decreases due to lower content. Although MD simulations did not consider the evaporation, correlating the MSD and bonding energy with patterns in HNMS patterns created after water evaporation vs. HNMS amphiphilicity for GNP CNC, CNT CNC and BNNT CNC suggests that for GNP:CNC (12:1) in evaporating droplet, formation of disk is more plausible than ring as GNP and CNC move slowly and GNP aggregates due to GNP & GNP high bonding energy. In contrast, for GNP:CNC (1:4), high bonding energy of CNC & water and accelerated movement of CNC and GNP (towards droplet edge in evaporation) imply ring is more plausible to form as seen in FIG. 6.

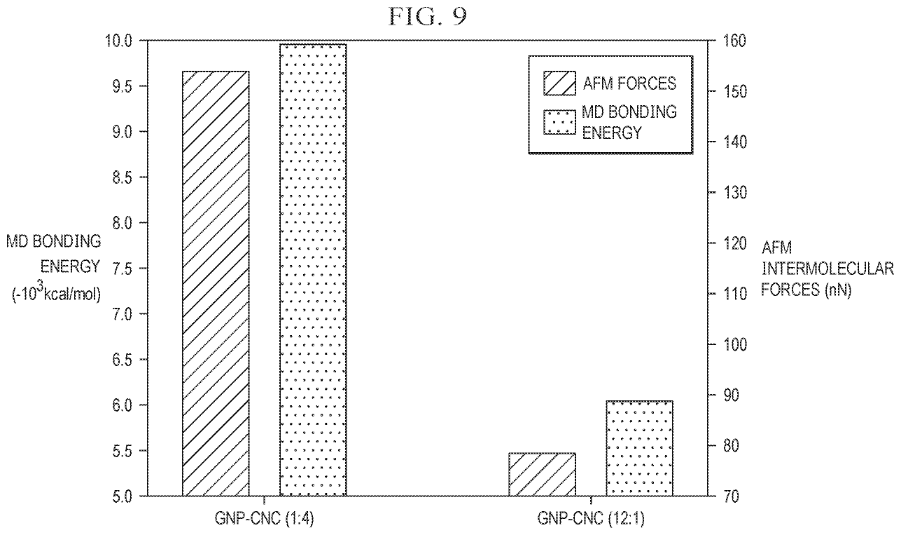

To validate the accuracy of the MD calculations, all bonding energies were added for a specific ratio and compared with resultant AFM forces (FIG. 9). The MD total bonding energies is 40% and the AFM intermolecular force is 47% higher for GNP-CNC (4:1) compared to those of (12:1). Despite this agreement, 7% discrepancy is possibly because MD simulation did not consider the GNP-CNC as a unified HNMS in contrast to AFM experiments. The MD resolved the individual forces; however, the effects of (i) substrate and polarity of solvent, (ii) bonds between NMs that build HNMS and its amphiphilicity, and (iii) evaporation must be revealed to complete general understanding.

Irrespective of the shape and type of NMs, the amphiphilicity degree of HNMS and the ratio of the droplet's diameter-to-HNMS' total mass inside droplet determine the balance of attractive, repulsive and directional intermolecular forces between HNMS, solvent and substrate, which in turn dictate the shape, size and height of the created NMs patterns.

The intermolecular forces of HNMS-solvent-substrate with various substrates (Al, SiO₂, Si, PDMS) and solvents (water (PI: 10.1), ethanol (PI: 5.2), and toluene (˜nonpolar)) will be characterized within a fluid cell (MMTMEC Bruker, heater/cooler fluid cell) in AFM (AFM, Bruker Dimension Icon). Custom-made colloidal cantilever AFM probes with spherical tips (Si or Au 1-6.6 μm) are coated with HNMS. Spherical tips allow homogenous coating. To understand the intermolecular forces of HNMS-HNMS in a solvent, the substrate was coated with HNMS and the intermolecular forces was determined in different solvents. These measurements revealed how the interplay of HNMS amphiphilicity, solvent polarity and substrate surface energy governed the resultant intermolecular force balance.

The steps for obtaining a suspension of nanoparticles are first and foremost, the separation/debundling of nanoparticles, followed by stabilization. In the case of carbon nanoparticles, especially GNP and CNT, sonication is used to initiate the debundling, which can then be stabilized by CNC particles. So far, the dispersion mechanism of CNF and carbon nanomaterials were explained through the electrostatic interaction (in CNF-CNT) and steric hindrance and hydrophobic interactions (in CNF-GNP). These interactions are sufficient to stabilize CNT/GNP with CNFs due to higher aspect ratio and higher charge density of CNFs compared to those of CNCs. Hence, the same dispersing mechanism may not work for CNCs. The observations from fundamental molecular experimental and simulation study suggest that in addition to physical interactions, there must be another type of interaction, i.e. chemical bonding: the reactive spots on GNP/CNT, i.e., the atoms encasing their inherent defects, host the hydroxyl groups on the CNC and form bonds between the two structures. These bonds, which we hypothesize, are irreversible and covalent, are one of the main mechanisms that result in stabilizing the debundled carbon nanoparticles in polar solvents.

To evaluate the effectiveness of this CNC in dispersing pCNT in water, the dispersion quality of CNC-pristine CNT (CNC-pCNT) was compared with the functionalized CNTs such as CNC-mild acid-treated CNT (CNC-f_{M}CNT), harsh acid-treated CNT and f_{H}CNT using UV-Vis spectroscopy. As harsh acid-treated functionalization is a common method to increase dispersibility of CNT/GNPs in solvents and particularly in water, we functionalized the CNTs using sulfuric acid and compared their characteristics with pCNTs. UV-Vis spectroscopy curves of CNC-pCNT and CNC-f_{M}CNT have peaks around the wavelength of 250 nm, which is in accordance with previous studies of CNT aqueous suspensions. CNC-pCNT and mildly treated CNC-f_{M}CNT curves show two peaks at 223 nm (—OH group) and 272 nm (graphite) indicating the presence of both CNC and CNTs.

The stability of the dispersion mechanism was monitored for 21 days, during which the CNC-pCNT was stable. However, the CNC-pGNP suspension remained stable for only 2 days, which can be attributed to the insufficient number of CNCs attached to the micron size pGNPs. It was shown that CNF was entangled over graphene nanosheet layers and the suspension was stable for three months. Steric hindrance and hydrophobic interactions between CNF and GNP facilitate the formation of an entangled network and highly charged carboxyl groups of CNFs provide strong electrostatic repulsion for stable and uniform aqueous dispersion. The CNC-CNT/GNP interactions are in the form of physical interactions between the carbon body of the molecules and covalent bonds between the defects on the CNT/GNP and the nucleophile functional groups on CNC.

Multiple orientations of CNC to pCNT/pGNP were constructed to obtain the most stable energy configuration for the suggested bonding. This was followed up by studying the potential reaction paths and the Gibbs free energy values with three common carbon defects, i.e. single vacancy (sv), double vacancy (dv), and Stone-Wales (sw) Here, CNC is modeled with glucan chains. Simulations involving a more realistic models, a bundle of glucan chains, were also conducted which returned similar results. Starting from similar positions, the reaction path involving a single vacancy defect concludes a spontaneous reaction. Changes in the enthalpy shows the energy change in a thermodynamic system during the reaction and its negative values is considered a sign for the reaction's favorability as it releases energy and stabilizes. Changes to the Gibbs free energy, which includes both enthalpy and entropy changes between the initial and the final states, is another quantitative indicative of the reaction. Therefore, a declining pattern (all negative values) in both enthalpy and Gibbs free energy, means the reaction is theoretically barrierless, while an incline means the reaction requires input energy to occur. Here, both Gibbs free energy and enthalpy values change attest that the single vacancy defect is a viable path of CNC-svCNT reaction without an energy barrier. However, the CNC-svGNP reaction requires a small amount of energy, which is potentially provided by the sonication energy. The double vacancy (dv) and Stone-Wales (sw) defects are also more thermodynamically favorable than the pristine conditions. The sw and perfect CNT/GNP create an endergonic reaction with CNC and water, whereas sv and dv demonstrate more stable complexes in reaction path calculations. Overall results indicate that the covalent bonding formation is possible for all types of defected CNTs/GNPs with CNCs.

Despite their similarities, the reaction path of the pGNP system, both in enthalpy and Gibbs energy, has different highlights compared to that of pCNTs. The energy of the transitional state for the pGNP's reaction path is much higher than pCNT's. This can be attributed to the absence of curvature that abates spatial hindrance for pCNT. This is also responsible for the difference in the final energy state between CNC-pGNP, and CNC-pCNT, which is about 30% lower in the case of CNC-pGNP.

The bonding state is also examined in the radial distribution factor (RDF). Here, the oxygen atoms on CNCs are evaluated based on their distance from the carbon atoms of pCNTs/pGNPs. While the covalently bonded carbon and oxygen atoms show an RDF value of around 1.48 Å, the RDF value of C(pCNT)-O(CNC) revolves around 1.51 Å, which closely resembles similar chemical bonds. The resulting C(pCNT)-O(CNC) bond indicates one of the carbon atoms on the periphery of the defect has bonded with one of the oxygen atoms on the CNC. The resulting C—O bond stands at 109° from the pCNT surface. The single vacancy defect shows more reactivity, mainly due to the unsatisfied state of carbon. As a result of CNC-pCNT bonding, the chemical properties of the resulting hybrid systems slightly change from a non-polar pCNT to a more polar hybrid nanostructure, which indicates the tendency for covalent bonding. The existence of the defect, by itself, demonstrates no significant chemical changes. Similar results are also observed for pGNP.

The reaction paths calculate the required energy for covalent bonding between CNC and pGNP/pCNT, and their three types of defects. A C—O bond formed between one of the peripheral carbon atoms of the defects and an oxygen atom of CNC's hydroxyl functional groups. The results reveal the possibility of the covalent bond forming, especially with single vacancy defects. This suggests that the interactions of CNC-single vacancy result in spontaneous C—O covalent bonding. Single vacancy bond energy in CNC-pCNT is at 75 kcal/mol, which is on par with the 81.1 kcal/mol from the single vacancy bond in CNC-pGNP. Coupled with the corresponding Enthalpy and Gibbs free energy, the energy values show the interactions between CNC-double vacancy and CNC-Stone-Wales vacancy can be considered weaker compared to CNC-single vacancy, indicating that the covalent bonding among CNC and the two former defects will form once the required energy is provided. This conclusion is also supported by comparing the corresponding bond length.

To validate the accuracy of the model systems used in the DFT calculations, the infrared (JR) spectra were calculated by DFT and compared with experimental FTIR results obtained for bulk CNC, CNC-pCNT, and CNC-pGNP. The agreement between IR calculation of a cellulose monomer and experimental FTIR spectra confirms that cellulose monomer and the level of theory is a reasonable model for CNC. The results are in good agreement such as the C—H peak at 2905 CM⁻¹ for all spectra (CNC and CNC-pCNT) except for a small shift in the OH stretching frequency at around 3400 CM⁻¹. Furthermore, there is good agreement at ˜3410 CM⁻¹ hydroxyl group, ˜2800 CM⁻¹ C—H, ˜1300 CM⁻¹ C—H, and ˜1000 CM⁻¹ C—O pyranose ring skeletal vibrations between the experimental FTIR and DFT calculated IR spectra of CNC-svCNT and nonbonding CNC-pCNT. The samples were dried to remove noise from moisture, and the peak at 1650 cm⁻¹ corresponding to water H—O—H bending mode, is most likely due to humidity in the air. The DFT calculated spectra of non-bonded CNC-pCNT/pGNP and covalently bonded CNC-svCNT/svGNP complexes present a similar trend to each other, where both plots match at OH, C—H, and C—O. The oxygen-containing functional groups give rise to bands at 1063, 1264, and 1385 cm⁻¹, indicating the C—O vibration of alkoxide, epoxy/ether, and hydroxyl groups, respectively. The modeled CNC-svCNT shows a broad range peak between ˜1500 and 1000 CM⁻¹, whereas experimental CNC-pCNT has many peaks at this range including C═C and C—C groups because of the available carbon sites of non-bonded CNC-pCNT. Furthermore, in the experimental spectra, pre-existing C—O groups in CNCs are indistinguishable from newly formed covalent bonds. Calculated and experimental IR spectrum does not distinguish the covalent bonding (CNC-svCNT/svGNP) and nonbonding interaction (CNC-pCNT/pGNP), but provides a general tool to verify the reliability of DFT calculations.

This work unravels a new mechanism for the stabilization of hydrophobic pCNTs/pGNPs in polar media by using CNC with no chemical functionalization or other additives. The TEM micrographs suggest CNCs approach to pCNTs/pGNPs by two methods: (1) side-by-side that create nonbonding physical interactions such as van der Waals and C-π and (2) from the tip-to-side on the defected areas of CNT/GNPs. Within these interactions, the shift in XPS O1 s in CNC-CNT/GNP indicates the formation of a new C—O chemical bond between CNC and pCNT/pGNP in addition to physical interactions. These bonds are in form of covalent interactions between available hydroxyl groups and other oxygen containing groups (e.g., sulfate group) on CNC and the carbon atoms on the periphery of defects on the carbon nanoparticles.

Cellulose nanocrystals (CNCs) enable the effective coating of carbon fibers with pristine carbon nanotubes (CNTs) and graphene nanoplatelets (GNPs). Herein, we articulate the mechanisms that form the interface of CNC-bonded CNT and CNC-bonded GNP-carbon fiber reinforced polymer (CFRP) composites. We show that CNC provides a suitable platform to engineer the interface of hybrid composites. We demonstrate the hybrid nanomaterials, i.e. CNC and CNT/GNP, alter the chemical composition of the interface and its properties, and despite the similar elemental composition of CNT and GNP, mechanical properties of the produced composites differ. Our results show that the presence of CNC-CNT and CNC-GNP creates a 4 μm interfacial region that leads to a 200% and 145% increase in interfacial shear strength (IFSS) and a 46% and 28% enhancement in interlaminar shear strength (ILSS), respectively. Furthermore, density functional theory (DFT) calculations show that the binding energy between CNC-CNT and carbon fiber (CF) sizing agent is 14% higher than that of CNC-GNP underlining the effect of chemical and physical interactions in the observed difference in mechanical properties. The understanding gained from this study highlights a path forward bottom-up manufacturing of hybrid composites with engineered microstructure and properties from the molecular level and nanoscale to higher scales.

Achieving desired performance from self-assembly of nanoparticles is very challenging due to the complex nature of interactions among the constituent building blocks. Self-assembly of Nano-colloids through evaporation of particle-laden droplets can be exploited to fabricate tailored nanostructures that add functionality and engineer the properties of the manufactured components. In this study, we use unique amphiphilic properties of cellulose nanocrystals (CNCs) to make hybrid system of graphene nanoplatelets (GNPs) and CNCs and engineer the architecture of assembled nanostructures. We then employ a novel atomization system for high-throughput deposition of precisely controlled carrier droplets that form desired 3D patterns on various substrates.

Bottom-up nanofabrication processes for constructing engineered 3D micro/nano-structures have been widely studied as one of the most critical aspects of nanotechnology. Bottom-up techniques entail some form of self-assembly of the building units within the system, such as atoms, molecules, and colloids, that cluster together, reach an equilibrium state, and create a nanostructure with a specific pattern (i.e., shape, size, thickness).

The supercritical CO₂ assisted atomization (SAA) system described herein enables formation of micron-sized carrier droplets with a narrow size distribution. Moderate operating conditions (i.e., temperature and pressure), low viscosity, high density and diffusivity, and high miscibility of CO₂ in water and most organic solvents extends its compatibility with a wide range of materials and promotes its scalability as a viable option for large scale deposition of NPs with desired properties on various substrates. In addition, sensitivity of the system to slight changes of temperature and pressure allows the user to easily adjust the process parameters to achieve specific carrier droplet attributes (e.g., size, flow rate, temperature, coverage) based on the requirements of the deposition application.

In an embodiment of the claimed invention, a nanoparticle-agnostic approach that allows the fabrication of multi-material nanostructures with precisely engineered patterns is used. A novel spray atomization system is used to generate fine and homogenous droplets as NP carriers for deposition of 3D nanostructures with desired architecture on different substrates. The functionality of these multi-material systems and achieve different degrees of electrical properties by engineering the pattern of deposited nanoparticles is also characterized. The developed system involves non-toxic, abundant, and biocompatible agents such as water, CNC, and CO₂ that promote its scalability and adaptation.

The SAA system consists of two main feed lines where CO₂ and the injection suspension are pumped into a pressure vessel and the tertiary mixture (i.e., CO₂, solvent, and NPs) resides to have sufficient time for the gas dissolution into the water. The temperature and pressure in the vessel are precisely controlled to remain at the critical point of the CO₂ (i.e., 31.5° C. and 7.5 MPa). The multiphase mixture is then injected into the ambient pressure and temperature and towards the substrate of interest through an atomizer with a micron sized injection orifice (125 μm). The injector is actuated and controlled using an Arduino microcontroller system to operate down to 1-ms resolution. The supercritical CO₂ that is dissolved in the colloidal suspension forms gas bubbles that expand and burst upon injection into ambient temperature and pressure, which results in breakup of the liquid jet and formation of fine NP carrier droplets.

Stencil masking, which is a non-intrusive approach for controlling the deposition site, can easily be integrated with the SAA system. Masking combined with precise control over injection duration in SAA enables the engineering of shape and thickness of coatings on any solid substrate.

MD simulations are further used to track the dynamics of NPs and trace their movement in water droplet over time (i.e., Brownian motion) that results in formation of specific pattern. FIG. 10A-FIG. 10C compares the movement of NPs, CNCs, and water molecules over time by measuring the mean squared displacement values (MSD) for HNMS with different amphiphilicity degrees. MSD itself is the cumulative displacement of a certain particle over time. The MD model to simulate the CNC-NP is representative HNMS in a water droplet with a total of ˜55,000 atoms (45K water atoms=15K molecules) and a total of 10,000 atoms of CNC and NP with different ratios.

Comparing FIG. 10A1-FIG. 10C1 and FIG. 10A2-FIG. 10C2 shows that with higher NP to CNC ratio (i.e., hydrophobic-dominant HNMS), the mobility of NPs, represented by MSD values, is lower. This is possibly a result of NP aggregation. Simultaneously, water molecules show high mobility; this is because the aggregated phase is separated from the water phase, severely limiting their interaction. This allows the majority of the water molecules to move unhindered. In contrast, when NP to CNC ratio drops (i.e., hydrophilic-dominant HNMS), the movement of water molecules becomes restricted, while the CNC particles start to move more freely in the droplet. This is due to increasing water—CNC interactions that, while constricting the movement of water molecules, attach them to CNC molecules and greatly increase CNCs' mobility. Interestingly, in these hydrophilic-dominant samples, the MSD values for the NPs increase, possibly because of reduced NP aggregation. For instance, comparing FIG. 10A1 and FIG. 10A2 at 250 ps time scale shows that when GNP content is higher, and CNC is lower (12:1 compared to 1:4), the MSD of GNP and CNC is lower (˜40 Å² and 12² compared to ˜200 Å² and 70 Å²), and MSD of water molecules is higher (˜700 Å² compared to ˜500 Å²). Although MD simulations did not consider the evaporation, correlating the MSD and interaction energy with previous patterns suggests that for hydrophobic-dominant HNMS in the evaporating droplet, the formation of a disk-shaped pattern is more plausible than the ring as CNCs move slowly, and NPs aggregate due to the high interaction energy of NP-NP. In contrast, for hydrophilic-dominant samples, the high interaction energy of CNC-water and accelerated movement (i.e., high MSD values) of CNC and NP (towards droplet edge in evaporation) indicate that the formation of a ring-shaped pattern is more likely. It is worth emphasizing that the correlation of interaction energies and movement of particles with the final pattern that they create is independent of the size, shape, or material type of the NPs, and all the CNC bonded GNP, CNT, and BNNT pairs follow the same trend in this regard.

The term “substantially” is defined as largely but not necessarily wholly what is specified, as understood by a person of ordinary skill in the art. In any disclosed embodiment, the terms “substantially”, “approximately”, “generally”, and “about” may be substituted with “within [a percentage] of” what is specified, where the percentage includes 0.1, 1, 5, and 10 percent.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure. The scope of the invention should be determined only by the language of the claims that follow. The term “comprising” within the claims is intended to mean “including at least” such that the recited listing of elements in a claim are an open group. The terms “a”, “an”, and other singular terms are intended to include the plural forms thereof unless specifically excluded.

1. A method of deposition of nanostructures with engineered patterns, the method comprising:
selecting nanoparticles and a substrate; and
delivering the nanoparticles to the substrate via a supercritical CO₂-assisted atomization (SAA) system,
repeating the delivering step to form patterns on the substrate and to form a three-dimensional (3D) nanostructure.

2. The method of claim 1, wherein the nanoparticles comprise one or more of cellulose nanocrystals (CNCs), two- or three-dimensional carbonaceous nanomaterials, carbon nanotubes (CNTs), graphene nanoplatelets (GNPs), fullerene, ceramic nanoparticles, boron nitride nanobarbs (BNNB), nanotubes (BNNT) or nanosheets (BNNS), pristine CNT (pCNT), pristine GNT (pGNT), and combinations thereof.

3. (canceled)

4. The method of claim 1, wherein the three-dimensional structure is selected from the group consisting of rings, disks, domes, and combinations thereof.

5-6. (canceled)

7. The method of claim 1, wherein the nanoparticles comprise a first nanoparticle and a second nanoparticle.

8. The method of claim 7, wherein the first nanoparticle and the second nanoparticle have a ratio designed to create an engineered amphiphilicity that subsequently form a pattern.

9. A method of preparing colloidal suspensions of hybrid nanomaterials systems (HNMS) comprising two or more nanomaterials attached by chemical and physical bonds, the method comprising:
dispersing nanomaterials having different shapes, sizes, and elemental compositions in a solvent;
sonicating the solvent with a sonication probe to prepare the HNMS;
delivering the HNMS to a substrate via a supercritical CO₂-assisted atomization (SAA) system;
repeating the delivering step to form a pattern on the substrate; and
creating 3D nanostructures by composing patterns selected from the group consisting of rings, disks, domes, and combinations thereof.

10-12. (canceled)

13. The method of claim 9, wherein the patterns are created by engineering amphiphilicity degree of the HNMS, which itself is designed by the ratios of different nanomaterials used in the HNMS.

14. The method of claim 9, wherein the substrate comprises at least one of glass, polymer, ceramic, or semiconductors.

15. The method of claim 9, wherein the nanomaterials comprise one or more of cellulose nanocrystals (CNCs), two- or three-dimensional carbonaceous nanomaterials, carbon nanotubes (CNTs), graphene nanoplatelets (GNPs), fullerene, ceramic nanoparticles, boron nitride nanobarbs (BNNB), nanotubes (BNNT) or nanosheets (BNNS), pristine CNT (pCNT), pristine GNT (pGNT), and combinations thereof.

16-17. (canceled)

18. The method of claim 9, wherein the nanomaterials comprise a first nanoparticle and at least a second nanoparticle.

19. The method of claim 18, wherein the first nanoparticle and the second nanoparticle have a ratio designed to create an engineered amphiphilicity that subsequently create and form a pattern.

20-21. (canceled)

22. A method of making a cellulose nanocrystal (CNC)-bonded carbon nanotube carbon fiber reinforced polymer (CNT-CFRP) hybrid composite, the method comprising:
dispersing carbon nanotubes (CNTs) in a solvent with CNCs to form a mixture;
sonicating the mixture;
coating a carbon fiber (CF) fabric with the sonicated mixture to deposit the mixture on the CF fabric; and
manufacturing a CNC-CNT-CF/epoxy hybrid composite using vacuum assisted resin transfer molding (VaRTM).

23-28. (canceled)

29. A method of making a hybrid cellulose nanocrystal (CNC)-graphene nanoplatelet (boron nitride nanobarb) (GNP-(BNNB))-carbon fiber (CF)/polyether ether ketone (PEEK) using spray-coating, the method comprising:
dispersing BNNB, CNC, and GNP in a solvent to form a mixture;
treating a CF/PEEK prepreg with a plasma surface treatment;
coating the CF/PEEK prepreg with the mixture via a supercritical CO₂-assisted atomization (SAA) system; and
forming the hybrid CNC-GNP(BNNB)-CF/PEEK via compression molding of the CF/PEEK prepreg.

30-31. (canceled)

32. A cellulose nanocrystal (CNC)-bonded carbon nanotube carbon fiber reinforced polymer (CNT-CFRP) hybrid composite composition, wherein the composition is created via the methods of claims 22-24 or 29.

33-37. (canceled)

38. The method of claim 22, wherein the coating occurs via a supercritical CO₂-assisted atomization (SAA) system.

39. A method of making a cellulose nanocrystal (CNC)-bonded carbon nanotube carbon fiber reinforced polymer (CNC-CNT-CFRP) or CNC-bonded graphene nanoplatelets (GNP) carbon fiber reinforced polymer (CNC-GNP-CNT-CFRP) hybrid composite, the method comprising:
dispersing carbon nanotubes (CNTs) or graphene nanoplatelets (GNPs) in a solvent with CNCs to form a mixture;
sonicating the mixture;
forming patterns such as ring, disk and combinations thereof, on carbon fiber (CF) fabric with the mixture via a supercritical CO₂-assisted atomization (SAA) system; and
manufacturing patterned CNC-CNT-CF/epoxy or CNC-GNP-CF/epoxy hybrid composites using vacuum assisted resin transfer molding (VaRTM).
